(19) United States
(12) Patent Application Publication
(10) Pub. No.: US 2006/0168495 A1
(43) Pub. Date: Jul. 27, 2006

(54) Computation of cyclic redundancy check

(75) Inventors: Pushparaj Dominic, Bangalore (IN); Anshoo Tandon, Bangalore (IN)

Correspondence Address: WOLF GREENFIELD & SACKS, PC, FEDERAL RESERVE PLAZA, 600 ATLANTIC AVENUE, BOSTON, MA, 02210-2206, US

(73) Assignee: Analog Devices, Inc., Norwood, MA (US)

(21) Appl. No.: 11/042,795

(22) Filed: Jan. 25, 2005

(51) Int. Cl. H03M 13/00

(52) U.S. Cl. 714/758

(57) ABSTRACT

In one aspect, a method and apparatus for advancing a state of a cyclic redundancy check (CRC) computation on a transmitted message via a look-up table (LUT) storing a plurality of entries associated with possible states of the CRC computation is provided. A plurality of indexes is computed based on a message chunk and a current state of the CRC computation to obtain a plurality of entries from an LUT. The plurality of entries is used to determine an advanced state of the CRC computation. In another aspect, the LUT is accessed with the plurality of indexes in parallel. In another aspect the LUT includes fewer than 2^{k} entries, where k is the number of states advanced on each iteration.

### FIELD OF THE INVENTION

The present invention relates to cyclic redundancy check (CRC) computations, and more particularly to table look-up techniques for error detection using CRC.

### BACKGROUND OF THE INVENTION

Information transmitted electronically may be vulnerable to corruption due to various factors including noise in the transmission channel, intentional tampering, etc. For example, errors may be introduced to a message transmitted over a network by the transmission media and/or the electrical or optical components comprising the network. To establish the integrity of a message, a sender may attach a checksum to the transmitted message that can be employed by the recipient to check for any of various transmission errors that may occur while the message is being sent.

A simple example of a checksum implementation includes appending the sum of the bytes in the message at the end of the transmission. The recipient may then add up the bytes in the received message and compare it with the checksum. If one or more of the bytes in the message were corrupted during the transmission, the sum will not likely match the appended checksum, thus indicating that the message may have been corrupted. However, this relatively simple checksum technique will fail if the various bytes in the message are corrupted in such a way that individual byte errors compensate one another to result in a sum consistent with the checksum. The probability of a checksum technique failing to identify an error can be reduced by introducing more complex techniques than simple summing.

It should be appreciated that the term “checksum” refers generally to any information appended or otherwise included in a transmission indicating one or more properties of the message, and is not limited to sums or any other particular operation. For example, a checksum may be a quotient remainder, a product, a sum or may include one or more other transformations based on the content of the message. The term “message” herein refers to the content portion of an electronic transmission (i.e., without the checksum). The term “transmission” is used herein to describe the combination of at least the message and the checksum.

Cyclic redundancy check (CRC) methods involve forming a checksum from the remainder of a quotient of the message and a predetermined binary number. For example, the message may be considered as a large binary number, wherein the first bit in the message may operate as the most significant bit (MSB) of the number and the final bit in the message may operate as the least significant bit (or vice-versa). The message may then be divided by a predetermined binary number known to both the sender and receiver of the message. The sender attaches the quotient remainder as the checksum and the receiver repeats the division operation on the received message to ensure that it matches the transmitted checksum.

The efficacy of the above scheme to detect certain types of transmission errors depends, in part, on the binary number used as the divisor. Certain classes of divisors have properties that can more readily detect transmission errors of different types. Certain polynomials exhibit desirable properties (e.g., randomness that when operated on with using polynomial arithmetic, and more particularly, Galois field polynomial arithmetic, provides a basis for performing effective CRC computations.

FIG. 1A illustrates a polynomial 10. In binary Galois field arithmetic (GF (2)), coefficients for the terms in a polynomial may be either unity (1) or zero (0). Accordingly, polynomial 10 may be designated by showing its terms having unity coefficients (i.e., non-zero coefficients). Polynomial 10 may be represented as a binary number 12, wherein each bit position of the binary number represents the coefficient of a corresponding term in the polynomial, as illustrated in FIG. 1B. For example, since polynomial 10 has a non-zero first term (i.e., the x⁰ term), the LSB bit of binary number 12 is a one. Likewise, the MSB of binary number 12 corresponds to the highest exponent term of the polynomial (e.g., the coefficient value of the x¹⁵ term). Accordingly, the bit position of the coefficient value in the binary number implicitly provides the order of the associated term in the polynomial.

As discussed above, a message to be transmitted may be considered as a single large binary number. This binary number may then be divided by the binary representation of a chosen polynomial, referred to as a generator polynomial (e.g., polynomial 10 illustrated in FIG. 1). A sender of a message may divide the message by the generator polynomial to obtain a remainder and append the remainder to the message as a checksum. The resulting combination may then be transmitted to a recipient. The recipient may then remove the checksum from the transmission and repeat the division operation by dividing the message by the generator polynomial. If the two remainders match, the message is assumed to have been transmitted faithfully and without corruption.

CRC operations employing generator polynomials are typically done using Galois field arithmetic (sometimes referred to as polynomial arithmetic). In Galois field arithmetic, addition and subtraction are equivalent to a logical exclusive-OR (XOR) operation as shown in Table 1 below. Certain generator polynomials are known to have generally desirable characteristics that lend themselves to detection of a variety of transmission errors, while having a low probability of missing errors due to, for example, internal compensation. Numerous generally effective generator polynomials are known in the art. However, any generator polynomial may be used.

TABLE 1
Addition and Subtraction Galois Field

| | | |
|---|---|---|
| 0 | 0 | 0 |
| 0 | 1 | 1 |
| 1 | 0 | 1 |
| 1 | 1 | 0 |

A division operation in GF (2) may be performed by computing successive XOR operations between divisor and dividend. For example, FIG. 2 illustrates a division operation 200 between a message 220 and a generator polynomial 210 in GF (2). The operation is similar to conventional long division, but with XOR operations 205 (i.e., subtraction in Galois field arithmetic) at each partial division iteration. Division operation 200 results in a quotient 230 (which may be ignored) and a remainder 215. Remainder 215 may operate as a checksum appended to a message transmitted, for example, over a network. Since both transmitter and receiver apply the same generator polynomial, division operation 200 may be performed on the received message to ensure that the resulting remainder matches the appended checksum.

The division operation in FIG. 2 may be implemented as a linear feedback shift register (LFSR). FIG. 3 illustrates a divider including an LFSR configured to perform division of a bit stream by a generator polynomial. LFSR includes a plurality of storage elements or stages R₇-R₀, each capable of storing a single binary value and connected together so as to perform a left shift (i.e., binary values shift from R₀ towards R₇). Storage elements R₇-R₀ may be, for example, a shift register operating on a clock signal (not shown). A received message 355 may be loaded into the LFSR at stage R₀ and shifted through the LFSR. For example, on each clock pulse, the contents of each storage element may be shifted one element to the left via shift connections Cₙ-C₀ such that values shift from the LSB at R₀ to the MSB at R₇. Together, the values stored in the stages of LFSR 300 at any given time define a state or state vector of the LFSR. The term “state” or “state vector” refers to a value, often a binary number, arrived at during a CRC computation. For example, the state of an LFSR may be the value stored in the shift register or designated portion of the shift register as described in more detail below.

As message 355 is shifted through the LFSR, the state vector continues to change, based on the content of message 355 and the feedback connections or “taps” formed at various stages of the LFSR. For example, LFSR 300 includes feedback connections 310a and 310b, which provide the value stored at the MSB of the register to a respective summing element 325a and 325b situated between predetermined stages of the LFSR. The summing elements perform modulo-2 arithmetic on their inputs (i.e., the summing elements perform a logical XOR operation on respective input values). The feedback connections are arranged according to the generator polynomial being used. For example, feedback connections 310a and 310b implement the generator polynomial shown in the division operation of FIG. 2. Each non-zero coefficient in the generator polynomial has a corresponding feedback connection (with the exception that the non-zero coefficient corresponding to the highest order term may not have any associated feedback connection, but provides the feedback value as described in further detail below).

A received message may be shifted through LFSR 300 as a binary stream from right to left. As the message is shifted through the LFSR, the feedback connections perform a division operation equivalent to the operation shown in FIG. 2. The final state vector, after the entire message has been shifted into the LFSR, is equal to the remainder of the division operation. For example, FIGS. 4A-4E illustrates an LFSR implementation of the division operation shown in FIG. 2. In FIG. 4A, the message has been shifted so that the MSB of the message is stored by the MSB of the LFSR. It should be appreciated that the first seven shifts required to place the message as shown in FIG. 4A will not affect the state since the MSB will be zero for these preliminary shifts such that the feedback connections will have no effect.

As the MSB of message 220 is shifted out of the LFSR (e.g., on the next clock pulse), feedback connections 410a and 410b take on a value of 1. As a result, the value in storage element R₄ will be XOR'ed with feedback connection 410a and the result shifted into storage element R₅. Likewise, the value in R₃ is XOR'ed with feedback connection 410b and the result is shifted into storage element R₄. The result after the first modular shift is shown in FIG. 4B. It should be appreciated by inspection that the state of the LFSR matches the result obtained after the first XOR operation 205 in FIG. 2.

In the configuration illustrated in FIG. 4B, storage element R₇ holds a value of zero. Thus, the feedback connections will have no effect on the next iteration and LFSR 400 will perform a simple shift to arrive at the state illustrated in FIG. 4C. The process is continued as shown in FIGS. 4C and 4D, until the final shift is made to arrive at the state illustrated in 4E. The state vector of LFSR 400 in FIG. 4E is equal to the remainder of the quotient of message 455 and the generator polynomial implemented by the feedback connections of the LFSR. At each shift of the LFSR, the state of the LFSR stores the same value as the corresponding XOR operation 205 in FIG. 2, therefore performing the desired division operation.

It should be appreciated that bits can be streamed into LFSR 400 to provide a division operation on any size message to perform a checksum validation. An LFSR may include any number of storage elements, i.e., the shift register may be of any length, and may implement any generator polynomial (e.g., the feedback connections may be of any configuration or arrangement to implement a desired generator polynomial). An LFSR may be implemented in hardware or software or a combination of both. While the hardware solutions are typically faster, software solutions provide generality and obviate the need to have dedicated hardware to perform CRC computations. For example, software solutions can easily incorporate and switch between any number of generator polynomials.

Software implementations, however, may significantly increase the computational cost of performing a CRC. In particular, the algorithm illustrated in FIGS. 2 and 4A-4E operate on a bit-by-bit basis. On each iteration, a single additional bit is processed (i.e., one bit of the message is shifted into the LFSR and one bit of the previous state vector is shifted out). As such, validating a checksum for an n-bit message requires at least n iterations. Each iteration may include a shift and numerous XOR operations that depend on the generator polynomial. As a result, CRC computations for large messages, implemented in software, may become prohibitively expensive. Also, processor architectures are often designed for optimal performance at word boundaries, for example, at byte, 16-bit, 32-bit, 64-bit boundaries, etc. Operating at the bit level may not be optimal for the processor and may further decrease the computational efficiency of a CRC.

Look-up tables (LUTs) have been employed to speed up CRC computation by allowing multiple bits to be processed in a single operation. By pre-computing states of the LFSR and storing the results in an LUT, multiple states may be bypassed via an index into the LUT. For example, in FIGS. 4A-4E, all the information needed to compute the remainder state vector shown in FIG. 4E is available at the time of the initial state in FIG. 4A. In particular, the intervening states between FIGS. 4A and 4E may be pre-computed using the known initial state and known feedback connections. The remainder state may be stored in an LUT and subsequently indexed by the initial state. That is, an advanced state associated with the initial state in FIG. 4A may be pre-computed and stored in the LUT. This can be repeated for every possible initial state, such that each initial state addresses an advanced state stored in the LUT. Therefore, multiple bits of a message may be processed simultaneously by advancing the LFSR multiple states without iterating through the intervening states.

The number of states that an LFSR may be advanced depends, in part, on the generator polynomial being used, and the number of bits of an incoming message that are simultaneously considered. In particular, the distance between an initial state and an advanced state (i.e., the number of intervening states) depends on the number of bits being considered that precede the first feedback connection. For example, in FIG. 5, the stages of register 520 preceding the first feedback connection store unmodified values of message 555 (i.e., bits b₀-bₙ). The stages after the first feedback connection store values that depend on the message as operated on by the feedback connections. For example, in one initial state, the first four values of message 555 (i.e., b₀-b₃) are loaded into register 520. The four most significant bits store values S at iteration zero. For example, at the beginning of a CRC computation, S may initially be set to all zeroes. LUT 550 is pre-computed in consideration of eight bit register 520 having a first feedback connection between the 4^{th} and 5^{th} bit. Accordingly, the advanced state associated with the initial state corresponds to the values in S at the iteration in which b₄ is shifted to a position just preceding the first feedback connection. Because of the manner the LUT was computed (i.e., computing advanced states from initial states having only four bits preceding the first feedback connection), LFSR 500 may only be advanced four states on each iteration.

The index 565 of LFSR 500 (i.e., the contents of register 520 at iteration zero) may be used to address LUT 550 to obtain the associated advanced state stored as an entry in LUT 550. The obtained advanced state may then be loaded into the LFSR, obviating the need to iterate through the intervening states. As shown, only the values of S at the next iteration (i.e., S(1)) are obtained from LUT 520, the values of register 520 preceding the first feedback connection are obtained by shifting message 555 into LFSR 500 a number of times equal to the number of states by which the LFSR has been advanced to form the next index into LUT 550. Accordingly, on each iteration four bits of the message are processed simultaneously.

### SUMMARY OF THE INVENTION

One embodiment according to the present invention includes a method for advancing a state of a cyclic redundancy check (CRC) computation on a transmitted message via a look-up table (LUT) storing a plurality of entries associated with possible states of the CRC computation, the method comprising acts of computing a plurality of indexes based at least on a current state and a message chunk of the transmitted message, each index of the plurality of indexes addressing a location in the LUT, obtaining a plurality of entries from the LUT, each entry acquired from the location indicated by a respective one of the plurality of indexes, and computing an advanced state based on the plurality of entries.

Another embodiment according to the present invention includes a computer readable medium encoded with a program for execution on at least one processor, the program, when executed on the at least one processor, performing a method of advancing a state of a cyclic redundancy check (CRC) computation on a transmitted message via a look-up table (LUT) storing a plurality of entries associated with possible states of the CRC computation. The method comprises acts of computing a plurality of indexes based at least on a current state and a message chunk of the transmitted message, each index of the plurality of indexes addressing a location in the LUT, obtaining a plurality of entries from the LUT, each entry acquired from the location indicated by a respective one of the plurality of indexes, and computing an advanced state based on the plurality of entries.

Another embodiment according to the present invention includes an apparatus for advancing a state of a cyclic redundancy check (CRC) computation on a transmitted message. The apparatus comprises an addressable storage area encoded with a look-up table (LUT), at least one input adapted to receive a message chunk from the transmitted message and a current state of the CRC computation, and at least one controller coupled to the at least one input, the at least one controller adapted to compute a plurality of indexes based on the message chunk and the current state, use each of the plurality of indexes to address a respective location of the LUT to obtain an entry from each of the locations, and compute an advanced state based on the obtained entries.

### BRIEF DESCRIPTION OF THE DRAWINGS

FIG. 1A shows a polynomial that may be used as a generator polynomial in a CRC computation;

FIG. 1B illustrates a binary representation of the polynomial shown in FIG. 1A;

FIG. 2 illustrates a polynomial division operation in Galois field arithmetic between a message and the binary representation of a generator polynomial;

FIG. 3 illustrates a linear feedback shift register (LFSR) implementing a generator polynomial and capable performing a division operation;

FIGS. 4A-4E illustrates the LFSR in FIG. 3 performing the division operation shown in FIG. 2;

FIG. 5 illustrates an LFSR being advanced by obtaining advanced states from a look-up table (LUT);

FIG. 6 illustrates an LFSR with an extended state vector to increase the number of states that may advance during a single iteration by accessing an LUT;

FIG. 7 illustrates a generalized LFSR capable of performing a division operation in a CRC computation, in accordance with one embodiment of the present invention; and

FIG. 8 illustrates a method of computing advanced in CRC computation by accessing multiple portions of a LUT to reduce the size of the LUT, in accordance with one embodiment of the present invention.

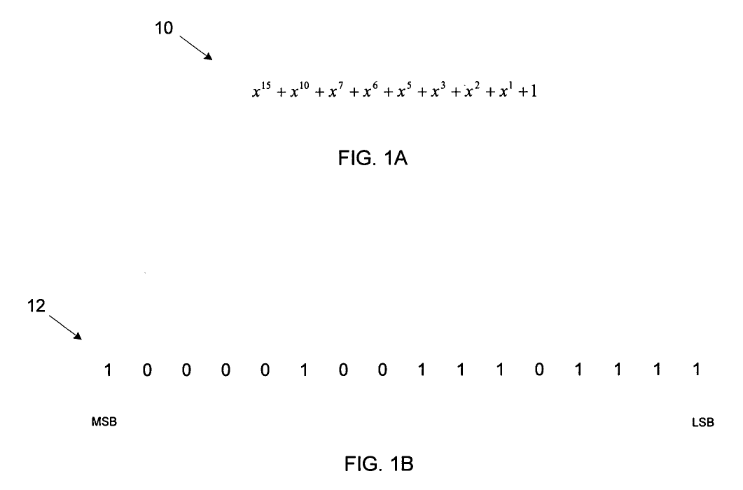

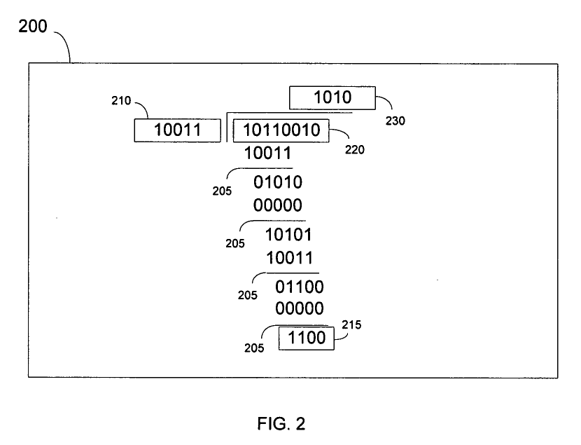

### DETAILED DESCRIPTION

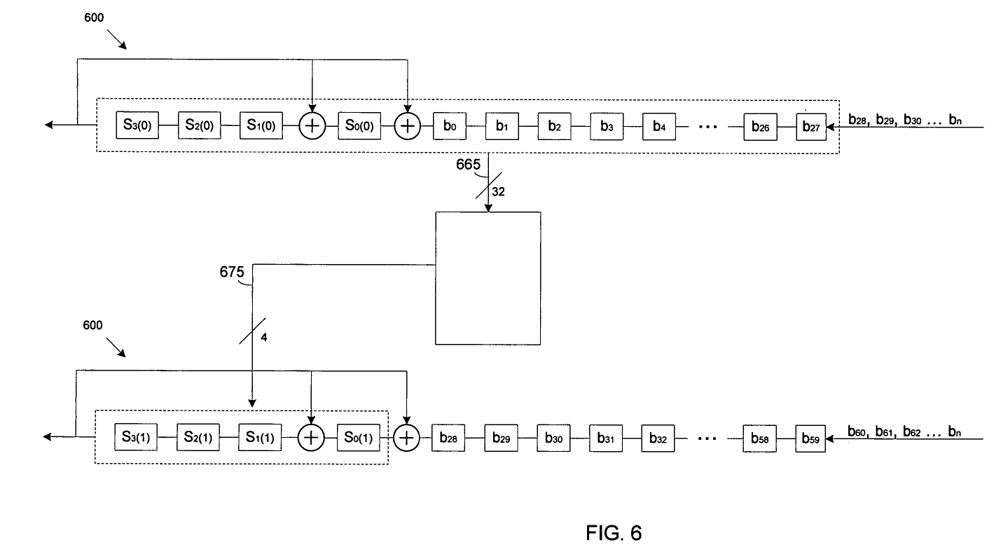

The number of states by which an LFSR may be advanced may be increased by considering more of the message preceding the first tap when computing an LUT. For example, in FIG. 6, LFSR 600 has been expanded to include thirty-six storage elements, thirty-two of which precede the first tap. Accordingly, LFSR 600 may be advanced thirty-two states before the first unknown bit b₀ reaches the first feedback connection 610b on a first iteration, before unknown bit b₃₂ reaches the first feedback connection on a second iteration, etc. However, to store an advanced state for each of all possible initial states (i.e., all possible combinations that could be stored by the 36-bit register), LUT 650 will include 2³⁶ entries. In general, an LUT for storing advanced states will have 2ⁿ entries, where n is the length of the index (e.g., the length of state vector of the LFSR).

An increase in the number of states by which a CRC computation is advanced on each iteration incurs a corresponding increase in the size of the LUT required to store possible combinations of advanced states. For example, the number of entries stored by an LUT typically increases as 2ⁿ, where n is the length of the index or state vector used to access the LUT. Applicant has identified and developed methods and apparatus for generating an LUT for a CRC computation that requires substantially less storage space than conventional methods. In one embodiment, multiple indexes are computed to address, in parallel, an LUT to obtain information from the LUT that, in combination, may be used to determine an advanced state.

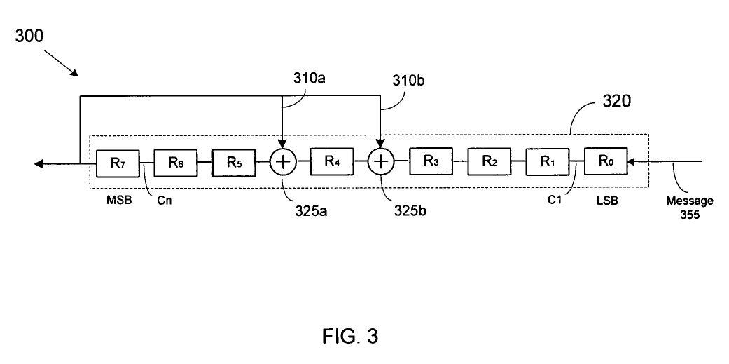

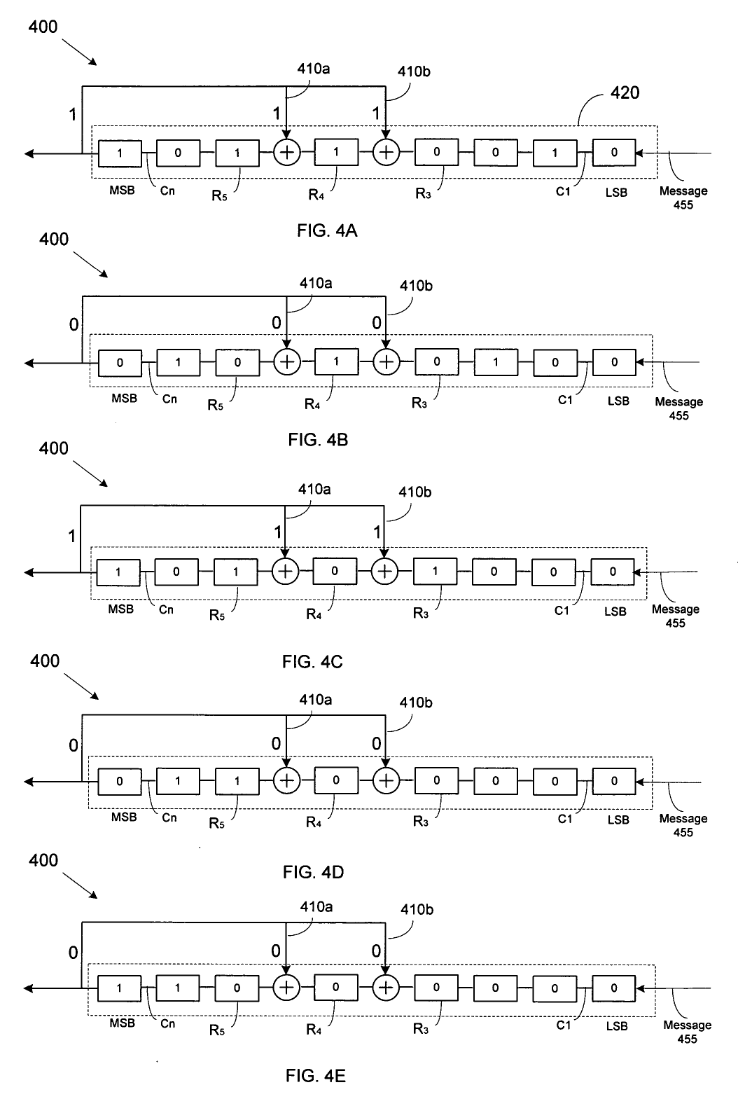

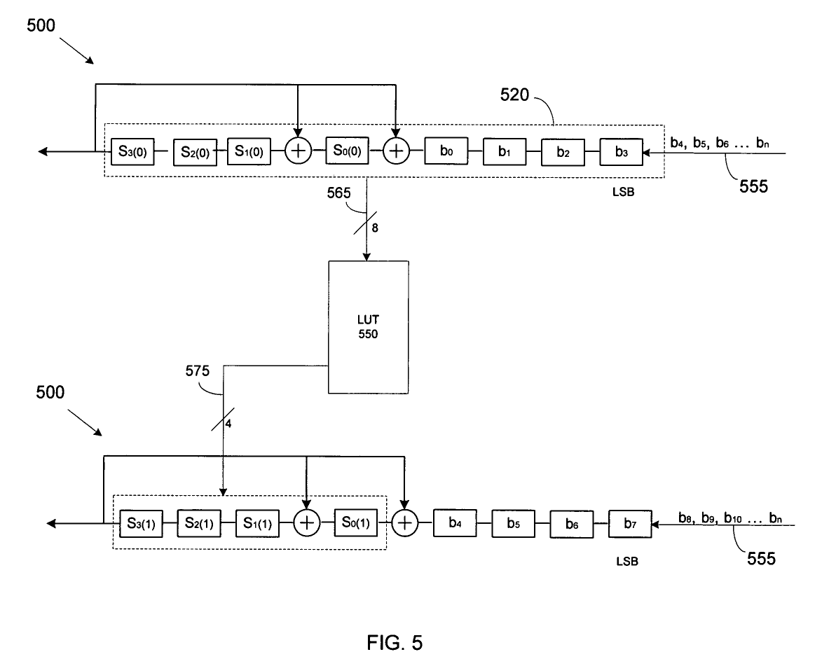

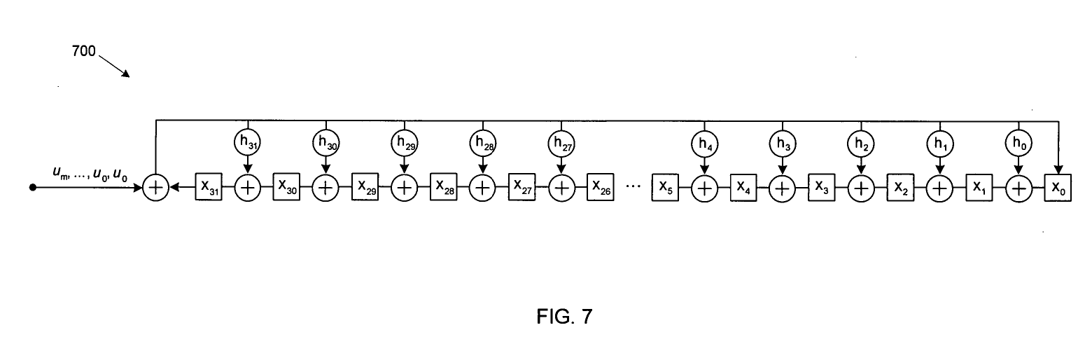

FIG. 7 illustrates a generalized version of an LFSR capable of implementing an arbitrary generator polynomial. LFSR 700 includes thirty-two stages x₀-x₃₁, which form the state vector of the LFSR, and a plurality of feedback connections or taps h₀-h₃₁, each of which can be set to either a value of one or zero to implement a desired generator polynomial. The generalized LFSR in FIG. 7 has a form slightly modified from the form of the LFSRs illustrated in FIGS. 3-6. In particular, a bit stream u (e.g., a transmitted message) comprising bits u₀-uₘ are introduced to the LFSR by performing an XOR between the lead unprocessed bit of u and the MSB of the shift register (i.e., by performing an XOR with the value stored in stage x₃₁). The result of the XOR operation is provided to each of the feedback connections and is also stored directly in the LSB of the shift register (i.e., the result is stored in stage x₀). It can be shown that the LFSR configuration in FIG. 7 is, to the extent that it performs a division operation between a generator polynomial (as implemented in the LFSR) and a binary number (e.g., the transmitted message), is functionally equivalent to the LFSRs illustrated in FIGS. 3-6.

As discussed above, computation times may be decreased by obtaining an advanced state from an LUT, rather than arriving at the advanced state by iteratively shifting u through the LFSR on a bit-by-bit basis (either physically in hardware, logically in software or a combination of both). Based on the generic form of LFSR 700, Applicant has developed methods for generating a LUT to store values pre-computed to advance an LFSR by k states, wherein the LUT has fewer than 2^{k} entries. In one embodiment, knowledge of the tap configuration (i.e., characteristics of the generator polynomial are used to generate an LUT that does not require storing an advanced state for an exhaustive list of possible initial states. This realization stems in part from Applicant's work in Galois field mathematics beginning with the formulation of the generalized LFSR in FIG. 7. The operation of LFSR 700 may be characterized as:

$$[ \begin{matrix}{x}_{31} ( k + 1 ) \\ {x}_{30} ( k + 1 ) \\ {x}_{29} ( k + 1 ) \\ ⋮ \\ {x}_{0} ( k + 1 )\end{matrix} ] = [ \begin{matrix}{h}_{31} & 1 & 0 & 0 & ⋯ \\ {h}_{30} & 0 & 1 & 0 & ⋯ \\ ⋮ & ⋮ & ⋰ & ⋰ & \\ {h}_{1} & 0 & ⋯ & 0 & 1 \\ 1 & 0 & 0 & ⋯ & 0\end{matrix} ] * [ \begin{matrix}{x}_{31} ( k ) \\ {x}_{30} ( k ) \\ {x}_{29} ( k ) \\ ⋮ \\ {x}_{0} ( k )\end{matrix} ] ⊕ [ \begin{matrix}{h}_{31} \\ {h}_{30} \\ ⋮ \\ {h}_{1} \\ 1\end{matrix} ] * {u}_{0} . \qquad ( 1 )$$

For scalar data, the * operator is used to indicate a bitwise AND operation. For vector and matrix data, the * operator is used to indicate the operation shown as follows:

$$\begin{matrix}Let A = [ \begin{matrix}a & b \\ c & d\end{matrix} ] and Y = [ \begin{matrix}e \\ f\end{matrix} ] , then & ( 2 ) \\ A * Y = [ \begin{matrix}a * e ⊕ b * f \\ c * e ⊕ d * f\end{matrix} ] & ( 3 )\end{matrix}$$

where, as mentioned above, the * operates on the scalar values inside the matrix in equation 3 as a bit-wise AND operation. The formulation in equation 1 may be expressed more succinctly as,
x(k+1)=A*x(k)⊕B*u₀ (4),

where x(k+1) is the state vector after the LFSR has been shifted from an initial state x(k). That is, column vector x₃₁(k) . . . x₀(k) represents the values stored in the stages of LFSR 700 at some reference instant (i.e., the column vector, denoted as x(k) in equation 4, represents an initial or current state of LFSR 700). Similarly, column vector x₃₁(k+1) . . . x₀(k+1) represents the state immediately succeeding the initial state x(k) after a single “shift” of the LFSR in view of a first bit u₀ of binary number u.

Matrix A depends on the tap configuration (h₀-h₃₁) and affects a shift of the LFSR. Matrix B also depends on the tap configuration and performs the operation of the feedback connections. It should be appreciated that matrices A and B include similar information. In particular,
B=A*[1,0,0, . . . ,0]^{T} (5).

This relationship may be used to simplify the expression in equation 4. For example, let k=0 to define an arbitrary initial state x(0). By multiplying u₀ by [1, 0, 0, . . . , 0]^{T} and substituting equation 5 into equation 4, equation 4 becomes,
x(1)=A*(x(0)⊕[u₀,0,0, . . . ,0]^{T}) (6).

Proceeding in a similar manner, the current state vector after the second shift (i.e., k=1) can be expressed as,
x(2)=A*x(1)⊕B*u₁ (7),
or,
x(2)=A*(x(1)⊕[u₁,0,0, . . . ,0]^{T}) (8),

where again, x(2) is the state vector after the second shift and u₁ is the second bit of u being introduced to the LFSR. Substituting the expression of equation 6 into equation 8 yields,
x(2)=A*(A*(x(0)[u₀,0,0, . . . ,0]^{T}))⊕A*[u₁,0,0, . . . ,0]^{T} (9).

It should be appreciated that A * [u₁, 0, 0, . . . , 0]^{T} is merely the first column of A multiplied by u₁. A*A (i.e., A²) results in a matrix having a second column equal to the first column of A. Applicant has appreciated that the operation A²*[0, u₁, 0, . . . , 0]^{T} extracts the second column of A², which is equal to the first column of A. That is,
A²*[0,u₁,0, . . . ,0]^{T}=A*[u₁,0,0, . . . ,0]^{T} (10).

The above equivalency allows equation 9 to be rewritten as,
A*(A*(x(0)⊕[u₀,0,0, . . . ,0]^{T}))⊕A²*[0,u₁,0, . . . ,0]^{T} (11).
Which may be simplified to,
A²*(x(0)⊕[u0,u₁,0, . . . ,0]^{T}) (12).

Taking further powers of A (i.e., A³, A⁴, A⁵, etc.) successively shifts the columns of the previous power to the right and generates a new first column. Accordingly, repeating the substitutions shown in equations 8-11, provides an expression for an arbitrary advanced state of the LFSR as follows:
x(N)=A^{N}*(x(0)⊕[u₀,u₁,u₂, . . . , u_{N}]^{T}) (13).

It should be appreciated that the advanced state x(N) is expressed in terms of an initial state x(0), powers of A and an N-bit chunk of u. For example, an advanced state advanced from an initial state by 32 states may be determined as follows:
x(31)=A³¹*(x(0)⊕[u₀,u₁,u₂, . . . ,u₃₁]^{T}) (14).

In general, an arbitrary advanced state may be determined by,
x(N)=A^{N}*(x(0)⊕u(0)) (15),

where A^{N} is an N×N matrix, x is a state vector of length N, and u is the next N bits of u (e.g., an N-bit message chunk of a transmitted message). Applicant has appreciated that A^{N} may be pre-computed, for example, to form a basis for a look-up table. By partitioning matrix A^{N} and the corresponding indexes, the ultimate size of the LUT may be reduced. For example, consider the case where N is chosen to be 31, and partition A³¹ as follows:

$${A}^{31} = [ {E}_{1} {E}_{2} {E}_{3} {E}_{4} ] , \qquad ( 16 )$$

where E₁, E₂, E₃, and E₄ are respective portions of A³¹, each being a matrix of size 32×8. From equation 15, let
Y=(x(0)⊕u(0)) (17),

and partition Y as follows:

$$Y = [ \begin{matrix}{Y}_{1} \\ {Y}_{2} \\ {Y}_{3} \\ {Y}_{4}\end{matrix} ] , \qquad ( 18 )$$

where Y₁, Y₂, Y₃, and Y₄ are the first, second, third and fourth bytes of Y, respectively. Accordingly, the state vector x(31) may be written as,

$$\underline{x} ( 31 ) = [ {E}_{1} {E}_{2} {E}_{3} {E}_{4} ] * [ \begin{matrix}{Y}_{1} \\ {Y}_{2} \\ {Y}_{3} \\ {Y}_{4}\end{matrix} ] , \qquad ( 19 )$$

which can be expressed as,

$$\underline{x} ( 31 ) = [ {E}_{1} * {Y}_{1} ] ⊕ [ {E}_{2} * {Y}_{2} ] ⊕ [ {E}_{3} * {Y}_{3} ] ⊕ [ {E}_{4} * {Y}_{4} ] . \qquad ( 20 )$$

In equation 20, each Eᵢ*Yᵢ is a vector of length 32. Keeping in mind the relative expense of the matrix operation *, computing Eᵢ*Yᵢ on each iteration of a CRC computation to advance the state may become prohibitive from a computational standpoint. However, Eᵢ may be pre-computed since it depends only on the configuration of the taps of the LFSR (i.e., Eᵢ depends only on the known generator polynomial). Accordingly, Applicant has appreciated that Eᵢ*Yᵢ may be computed for all possible values of Yᵢ to form a look-up table. For example, in the case where x(31) is being determined, each Yᵢ may be a byte long and therefore can take on 256 possible values (i.e., 0-255). Thus, computing Eᵢ*Yᵢ (e.g., where i={1, 2, 3, 4}) for all values of Yᵢ results in an LUT of the size 4×256. Accordingly, when a particular value of Y is obtained (i.e., by computing x(0)⊕u(0)), it can be used to index the LUT. For example, Y may be partitioned into multiple bytes Yᵢ and used to address respective locations in the LUT to obtain entries Eᵢ*Yᵢ. The entries obtained from the LUT may then be XOR'ed together (as shown in equation 18) to obtain the desired advanced state (e.g., x(31)).

It should be appreciated that the LUT may be viewed as a single LUT or as multiple LUTs, either of which may be addressed in sequence or in parallel. When performed in parallel, the information needed to determine an advanced state may be obtained substantially during a single read operation. The size of an LUT will depend on a chosen N, which may also influence how the LUT and indexes are partitioned. Any size may be chosen for N and any arrangement of partitioning may used, as the aspects of the invention are not limited in this respect.

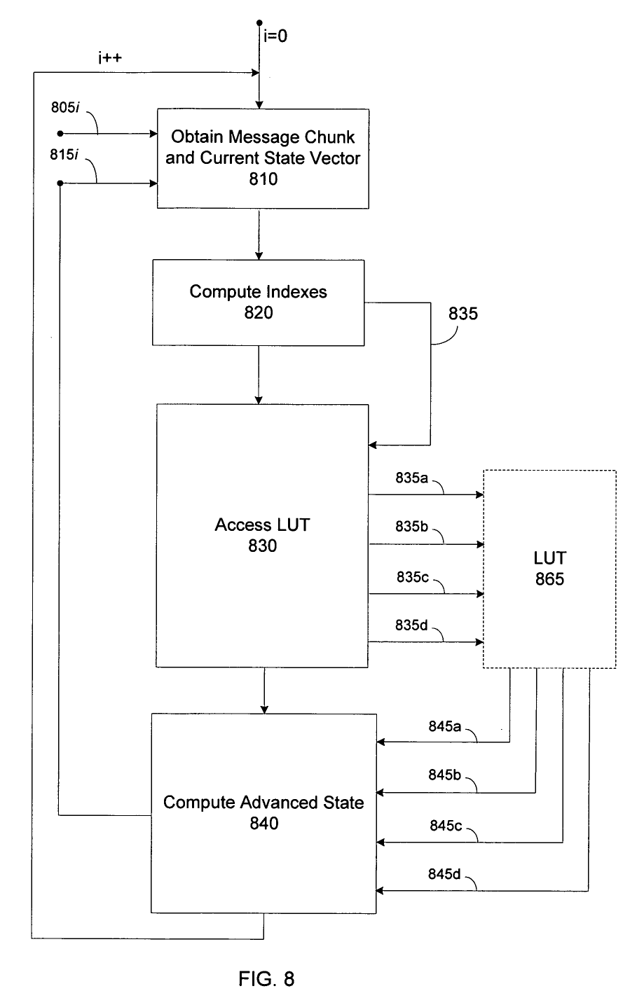

FIG. 8 illustrates a method for determining an advanced state of a CRC computation, in accordance with one embodiment of the present invention. For example, method 800 may be used to compute advanced states that, ultimately, result in a remainder calculation to validate a checksum on a message transmitted over a network. As discussed above, a checksum may be computed by dividing the message by a binary number corresponding to a generator polynomial known to both the sender and the receiver.

A look-up table 865 storing possible advanced states corresponding to a generator polynomial may be pre-computed. For example, a matrix A^{N} may be computed based on the generator polynomial for any desired value of N, where N generally indicates the number of states advanced on each iteration. However, in some implementations N may not exactly equal state advancement.

The matrix A^{N} may be used in connection with various combinations of initial states to compute advanced states corresponding to each of the initial states. For example, an index may be defined as shown in equation 14. The index Y typically will have a length equal to the larger of the length of the generalized LFSR state vector x and the length of the message chunk u being considered on each iteration, which may be chosen to be the same length. In one embodiment, the value of the index Y is the XOR of the initial state vector and the message chunk, as shown in equation 15. An initial state vector Y of length 32, therefore, may take on 2³² values.

In conventional LUTs, an initial state vector is used to obtain a corresponding advanced state from an LUT. Accordingly, an advanced state for each possible initial state is stored in the LUT. For example, for a 32-bit initial state vector, the LUT may have 232 entries to store advanced states for each of the possible initial states that a CRC computation may potentially be in. Applicant has appreciated that the index Y may be partitioned into a number of parts, with each part being considered in a substantially independent manner. For example, a 32-bit index Y may be partitioned into four byte length parts Y₁, Y₂, Y₃, and Y₄. When treated independently, each part may take on 28 different values for a total of 4×2⁸ (1024) possible values. By likewise partitioning matrix A³¹ into a corresponding number of portions (as shown in equation 16), an LUT of reduced size may be provided. In particular, all combinations of the first part of index Y (i.e., Y₁) may be multiplied by the first part of matrix A³¹ (i.e., E₁) to form a first portion of LUT 855. Likewise, all combinations of the second part of index Y (i.e., Y₂) may be multiplied by the second part of matrix A³¹ (i.e., E₂) to form a second portion of LUT 855. This process may be repeated until all corresponding portions of the LUT have been computed.

As discussed above, the index lengths and number of partitions illustrated herein are merely exemplary, and any desired configuration may be used to achieve a desired reduction in LUT size. As shown above, index Y and matrix A^{N} are generalized and can be dimensioned and partitioned in any way, and the aspects of the invention are not limited for use with any particular sizes, partitions and/or configurations. The pre-computed LUT 855 may then be indexed during a subsequent CRC computation, as discussed in further detail below.

Assume that in method 800, n bits of a transmitted message are to be considered simultaneously (i.e., the CRC computation may be advanced by n states on each iteration). In act 810, a first n bits of the message (i.e., message chunk 805ᵢ) and an initial or current state vector 815ᵢ associated with the CRC computation are obtained. For example, the current state vector may initially be a zero vector on the first iteration (i.e., on iteration i=0) or may take on some other initial value. It should be appreciated that when a CRC computation is implemented in software, a current state may simply be a number that is updated and maintained throughout the course of the computation. The term “current state” or “current state vector” refers herein to the state of a CRC computation at a given instant. Each current state may function as an initial state from which to compute an advanced state.

In act 820, message chunk 805ᵢ and current state vector 815i are employed to compute a plurality of indexes into LUT 855. In one embodiment, the message chunk 805ᵢ and current state vector 815ᵢ are XOR'ed together to form a concatenated index into look-up table 855 (e.g., forming concatenated index Y as shown in equation 15). The concatenated index may then be partitioned into a plurality of indexes 835 that address respective portions of LUT 855. For example, the concatenated index may include 32 bits, which are separated into four byte-length indexes 835a-835d.

In act 830, the plurality of indexes 835 formed from the concatenated index are used to access LUT 855 to obtain respective entries, for example, indexes 835a-835d may each reference an associated entry in LUT 855. Data at the associated addresses may then be acquired, e.g., entries 845a-845d may be read from the LUT, to obtain information about a corresponding advanced state. Indexes 835 may be logical addresses that map to addressable portions of the LUT, or may correspond to any other type of mapping that allows a value corresponding to the index to be retrieved from the LUT. For example, indexes 835 may undergo one or more operations to transform each index into the actual physical address of the corresponding entry in the LUT.

In act 840, entries 840 obtained from the LUT are employed to compute an advanced state vector advanced from the current state vector by n states, i.e., by a number of states equal to the length of message chunk 805ᵢ. For example, the entries 840a-840d acquired from the LUT may be XOR'ed together to form the advanced state vector 815ᵢ₊₁. The current state vector may then be updated to equal the advanced state vector for the subsequent iteration i⁺⁺.

Act 810 may then be repeated in a subsequent iteration using the updated current state (i.e., the advanced state computed on the previous iteration), in combination with the next n bits of the message, to compute new indexes into the LUT. This process may be repeated until all bits of the message have been processed, at which point the updated current state vector may represent the remainder of a division operation between the generator polynomial used to form the LUT 855 and the transmitted message. The obtained remainder may then be compared with the transmitted checksum to determine whether the message was corrupted during transmission.

It should be appreciated that the number of bits in the message chunk considered on each iteration may be any number, as the aspects of the invention are not limited for use with any particular choice of message chunk length, or the number of states advanced upon each iteration. In addition, a concatenated index may be of any length and may be partitioned into any number of indexes of any length to obtain any number of entries from the LUT. Similarly, the LUT may include any number of portions addressable by the indexes formed from the concatenated index.

In many processor architectures, it is common for operations to be applied to data having word length boundaries that may depend on the bus and/or register lengths of the processor. For example, bus widths may determine how much data is obtained in a single read operation and/or register lengths may determine how much data is transferred in load and store operations. By designing a CRC computation as described in connection with FIG. 8 to advance the state of the computation to complement the processor architecture, the CRC computation may be performed optimally. For example, implementing a 32-bit CRC on a 32-bit processor, or a 64-bit CRC computation on a 64-bit processor may allow for CRC computations that require fewer reads, writes, register manipulations, etc. to implement and perform the fundamental operations (e.g., XOR operations, LUT accesses, etc.) of the CRC computation.

In method 800, advanced state computations may be implemented with an XOR operation between a current state and a message chunk, a parallel index into the LUT, and XOR operations between the entries obtained from the LUT on each iteration. While other minor register operations may be required, from a computational standpoint, an iteration substantially consists of the above operations, providing a computationally efficient CRC. In addition, the CRC computation may be advanced by n states without requiring an LUT having 2ⁿ entries. For example, in the CRC computation illustrated in FIG. 8, message chunk 805ᵢ may include 32 bits such that each of the plurality of indexes provided to the look-up table is a byte in length. Therefore, LUT 855 need only include 256*4 entries to facilitate processing 32-bits of an incoming or received message on each iteration.

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers. It should be appreciated that any component or collection of components that perform the functions described above can be generically considered as one or more controllers that control the above-discussed function. The one or more controller can be implemented in numerous ways, such as with dedicated hardware, or with general purpose hardware (e.g., one or more processor) that is programmed using microcode or software to perform the functions recited above.

It should be appreciated that the various methods outlined herein may be coded as software that is executable on one or more processors that employ any one of a variety of operating systems or platforms. Additionally, such software may be written using any of a number of suitable programming languages and/or conventional programming or scripting tools, and also may be compiled as executable machine language code.

In this respect, it should be appreciated that one embodiment of the invention is directed to a computer readable medium (or multiple computer readable media) (e.g., a computer memory, one or more floppy discs, compact discs, optical discs, magnetic tapes, etc.) encoded with one or more programs that, when executed on one or more computers or other processors, perform methods that implement the various embodiments of the invention discussed above. The computer readable medium or media can be transportable, such that the program or programs stored thereon can be loaded onto one or more different computers or other processors to implement various aspects of the present invention as discussed above.

It should be understood that the term “program” is used herein in a generic sense to refer to any type of computer code or set of instructions that can be employed to program a computer or other processor to implement various aspects of the present invention as discussed above. Additionally, it should be appreciated that according to one aspect of this embodiment, one or more computer programs that when executed perform methods of the present invention need not reside on a single computer or processor, but may be distributed in a modular fashion amongst a number of different computers or processors to implement various aspects of the present invention.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. The invention is capable of other embodiments and of being practiced or of being carried out in various ways.

Also, the phraseology and terminology used herein is for the purpose of description and should not be regarded as limiting. The use of “including,” “comprising,” or “having,” “containing”, “involving”, and variations thereof herein, is meant to encompass the items listed thereafter and equivalents thereof as well as additional items.

What is claimed is:

1. A method for advancing a state of a cyclic redundancy check (CRC) computation on a transmitted message via a look-up table (LUT) storing a plurality of entries associated with possible states of the CRC computation, the method comprising acts of:
computing a plurality of indexes based at least on a current state of the CRC computation and a message chunk of the transmitted message, each index of the plurality of indexes addressing a location in the LUT;
obtaining a plurality of entries from the LUT, each entry acquired from the location indicated by a respective one of the plurality of indexes; and
computing an advanced state based on the plurality of entries.

2. The method of claim 1, further comprising an act of, prior to computing the plurality of indexes, computing the LUT based at least on a generator polynomial.

3. The method of claim 2, wherein the act of computing the LUT includes an act of computing the LUT based on a plurality of possible states.

4. The method of claim 1, wherein the act of computing a plurality of indexes includes an act of performing an XOR operation between the current state and the message chunk.

5. The method of claim 1, wherein the act of obtaining a plurality of entries from the LUT includes an act of performing a plurality of LUT accesses in parallel.

6. The method of claim 5, wherein the act of performing a plurality of LUT accesses in parallel includes an act of performing a parallel access such that the plurality of entries are obtained substantially within a single read cycle.

7. The method of claim 1, wherein the act of computing the advanced state includes an act of performing an XOR operation between each of the obtained entries.

8. The method of claim 1, further comprising an act of updating the current state with the advanced state.

9. The method of claim 8, wherein an iteration comprises, performing once, the acts of computing the plurality of indexes, obtaining a plurality of entries from the LUT, computing the advanced state, and updating the current state with the advanced state.

10. The method of claim 9, wherein performing the iteration consists computationally of a first XOR operation performed on the current state and the message chunk, a plurality of LUT accesses performed in parallel, and second XOR operations performed between the plurality of entries obtained from the LUT.

11. The method of claim 9, wherein the iteration is repeated for successive message chunks of the transmitted message such that, after each message chunk has been processed in a respective iteration, the advanced state is equal to a remainder of the message divided by a generator polynomial.

12. The method of claim 2, wherein the message chunk has a length of n=2^{k} bits.

13. The method of claim 12, wherein the advanced state is advanced from the current state by n=2^{k} states.

14. The method of claim 12, wherein the LUT consists of fewer than 2ⁿ entries.

15. The method of claim 14, wherein k=5.

16. The method of claim 15, wherein the LUT consists of no more than 1024 entries.

17. The method of claim 14, wherein k=6.

18. A computer readable medium encoded with a program for execution on at least one processor, the program, when executed on the at least one processor, performing a method of advancing a state of a cyclic redundancy check (CRC) computation on a transmitted message via a look-up table (LUT) storing a plurality of entries associated with possible states of the CRC computation, the method comprising acts of:
computing a plurality of indexes based at least on a current state of the CRC computation and a message chunk of the transmitted message, each index of the plurality of indexes addressing a location in the LUT;
obtaining a plurality of entries from the LUT, each entry acquired from the location indicated by a respective one of the plurality of indexes; and
computing an advanced state based on the plurality of entries.

19. The computer readable medium of claim 18, further comprising an act of, prior to computing the plurality of indexes, computing the LUT based at least on a generator polynomial.

20. The computer readable medium of claim 19, wherein the act of computing the LUT includes an act of computing the LUT based on a plurality of possible states.

21. The computer readable medium of claim 18, wherein the act of computing a plurality of indexes includes an act of performing an XOR operation between the current state and the message chunk.

22. The computer readable medium of claim 18, wherein the act of obtaining a plurality of entries from the LUT includes an act of performing a plurality of LUT accesses in parallel.

23. The computer readable medium of claim 22, wherein the act of performing a plurality of LUT accesses in parallel includes an act of performing a parallel access such that the plurality of entries are obtained substantially within a single read cycle.

24. The computer readable medium of claim 18, wherein the act of computing the advanced state includes an act of performing an XOR operation between each of the obtained entries.

25. The computer readable medium of claim 18, further comprising an act of updating the current state with the advanced state.

26. The computer readable medium of claim 25, wherein an iteration comprises, performing once, the acts of computing the plurality of indexes, obtaining a plurality of entries from the LUT, computing the advanced state, and updating the current state with the advanced state.

27. The computer readable medium of claim 26, wherein performing the iteration consists computationally of a first XOR operation performed on the current state and the message chunk, a plurality of LUT accesses performed in parallel, and second XOR operations performed between the plurality of entries obtained from the LUT.

28. The computer readable medium of claim 26, wherein the iteration is repeated for successive message chunks of the transmitted message such that, after each message chunk has been processed in a respective iteration, the advanced state is equal to a remainder of the message divided by a generator polynomial.

29. The computer readable medium of claim 19, wherein the message chunk has a length of n=2^{k} bits.

30. The computer readable medium of claim 29, wherein the advanced state is advanced from the current state by n=2^{k} states.

31. The computer readable medium of claim 29, wherein the LUT consists of fewer than 2ⁿ entries.

32. The computer readable medium of claim 31, wherein k=5.

33. The computer readable medium of claim 32, wherein the LUT consists of no more than 1024 entries.

34. The computer readable medium of claim 31, wherein k=6.

35. The computer readable medium of claim 29, in combination with the at least one processor, the at least one processor adapted to operate with a bus width of n.

36. An apparatus for advancing a state of a cyclic redundancy check (CRC) computation on a transmitted message, the apparatus comprising:
an addressable storage area encoded with a look-up table (LUT);
at least one input adapted to receive a message chunk from the transmitted message and a current state of the CRC computation; and
at least one controller coupled to the at least one input, the at least one controller adapted to compute a plurality of indexes based on the message chunk and the current state, use each of the plurality of indexes to address a respective location of the LUT to obtain an entry from each of the locations, and compute an advanced state based on the obtained entries.

37. The apparatus of claim 36, wherein the at least one controller includes means for computing the plurality of indexes based on the message chunk and the current state, means for using each of the plurality of indexes to address the respective location of the LUT to obtain the entry from each of the locations, and means for computing the advanced state based on the obtained entries.

38. The apparatus of claim 37, wherein the at least one controller includes at least one microprocessor, the at least one microprocessor adapted to access the LUT with the plurality of indexes in parallel such that the entries are obtained substantially in a single read operation.

39. The apparatus of claim 36, wherein the at least one controller is adapted to update the current state with the advanced state.

40. The apparatus of claim 39, wherein an iteration is completed when the at least one controller performs once computing the plurality of indexes based on the message chunk and the current state, using each of the plurality of indexes to address the respective location of the LUT to obtain the entry from each of the locations, computing the advanced state based on the obtained entries, and updating the current state with the advanced state.

41. The apparatus of claim 40, wherein computations during the iteration consist substantially of the at least one controller performing a first XOR operation on the current state and the message chunk, a plurality of LUT accesses performed in parallel, and second XOR operations performed between the plurality of entries obtained from the LUT.

42. The apparatus of claim 40, wherein the iteration is repeated by the at least one controller for successive message chunks of the transmitted message such that, after each message chunk has been processed in a respective iteration, the advanced state is equal to a remainder of the message divided by a generator polynomial.

43. The apparatus of claim 36, wherein the message chunk has a length of n=2^{k} bits.

44. The apparatus of claim 36, wherein the advanced state is advanced from the current state by n=2^{k} states.

45. The apparatus of claim 43, wherein the LUT consists of fewer than 2ⁿ entries.

46. The apparatus of claim 45, wherein k=5.

47. The apparatus of claim 46, wherein the LUT consists of no more than 1024 entries.

48. The apparatus of claim 45, wherein k=6.

49. The apparatus of claim 38, wherein the at least one microprocessor is a n-bit microprocessor and the CRC computation is advanced n states on each iteration.
